(19) United States
(12) Patent Application Publication
(10) Pub. No.: US 2006/0099817 A1
(43) Pub. Date: May 11, 2006

(54) Novel slurry for chemical mechanical polishing of metals

(75) Inventors: A. Daniel Feller, Portland, OR (US); Chris E. Barns, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/301,826

(22) Filed: Dec. 12, 2005

Related U.S. Application Data
(62) Division of application No. 10/676,330, filed on Sep. 30, 2003.

(51) Int. Cl. H01L 21/302; H01L 21/461

(52) U.S. Cl. 438/745; 438/740

(57) ABSTRACT

A slurry for removing metals, useful in the manufacture of integrated circuits generally, and for the chemical mechanical polishing of noble metals particularly, may be formed by combining periodic acid, an abrasive, and a buffer system, wherein the pH of the slurry is between about 4 to about 8.

This U.S. patent application is a continuation of U.S. patent application Ser. No. 10/676,330 filed Sep. 30, 2003.

### FIELD OF THE INVENTION

The present invention relates to the field of microelectronic processing, and more particularly to slurries and methods for chemical-mechanical polishing of metals.

### BACKGROUND OF THE INVENTION

The manufacture of microelectronic devices involves the fabrication of multiple electronic devices such as transistors, diodes and capacitors in and on a silicon or other semiconductor wafer, and then interconnecting the devices with metal lines, plugs and vias.

During the manufacture of a microelectronic device, a number of layers of different materials are alternately deposited on one another and then partially removed. One technique for removal of layers on a substrate, such as a semiconductor wafer for example, is known in the art as chemical-mechanical polishing (CMP). In a CMP operation, a CMP slurry is applied over a layer, such as a metal layer, in which the slurry serves both a chemical and a mechanical function.

Chemically, the slurry usually includes an oxidizer which may oxidize a metal layer by removal of electrons therefrom. The oxidized film that is formed is then capable of removal by the CMP process.

Mechanically, a slurry of the above kind also includes an abrasive such as silica (SiO₂) or ceria (CeO₂). The purpose of the abrasive is to abrade the oxidized film when a polishing pad is pressed against and moved over the film, and so remove the film.

Once the oxidized film is removed, the freshly exposed metal may again be oxidized to form another oxidized film which is again removed utilizing the abrasive. The process is continued until the metal layer is removed to a required depth. However, in the case of materials that are chemically stable and mechanically hard, such as noble metals, it may be more difficult to oxidize such a film. Thus, in the case of noble metals, a typical slurry used in a CMP process may not be capable of removing such a layer from a device.

Another problem associated with the use of CMP slurries is that they commonly have pH values which are less than about 3. Slurries having pH values which are less than about 3 tend to be corrosive and may be the cause of damage to polishing equipment used in a chemical-mechanical polishing operation. In addition, slurries with pH's that are less than about two are considered hazardous materials and therefore require special handling procedures which substantially increase manufacturing costs. For example, ruthenium, if oxidized at a pH of about 2, may form RuO₄ that can be both toxic and explosive. Additionally, low pH slurries readily react and cause corrosion of the polishing apparatus. As such, low pH slurries have been found inadequate to manufacturably chemically mechanically polish films in an integrated circuit process.

Therefore, there is a need for an improved slurry for the chemical mechanical polishing of metals, such as noble metals. The present invention provides such a slurry and its associated methods structures.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1f represent cross-sections of structures that may be formed when carrying out an embodiment of the method of the present invention.

FIGS. 2a-2f represent cross-sections of structures that may be formed when carrying out an embodiment of the method of the present invention.

FIGS. 3 represents a flowchart of a method according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Slurries and methods for removing metals are described. The slurry may be formed by combining periodic acid (HIO₄), an abrasive, and a buffer system, wherein the pH of the slurry may be maintained at a pH of between about 4 to about 8. The slurries and methods of the present invention may be used to form metal interconnect structures or metal gate electrodes commonly used in the fabrication of microelectronic devices, however, the slurries and methods of the present invention may also be used in other processes in the manufacture of microelectronic devices, as well as in areas other than microelectronic device processing.

An exemplary slurry, in accordance with the present invention, for chemical mechanical polishing, has a pH of about 4 to about 8, and is preferably between about 6.7 and about 7.1. The slurry of the current embodiment may include an abrasive, such as silica, ceria, zirconia or alumina, or any other suitable abrasive. The slurry may include between about 1 percent and 30 percent of the abrasive by weight, and may preferably comprise between about 1 percent and 5 percent of the abrasive by weight.

The slurry of the present invention may be maintained at a pH of about 4 to about 8, and is most preferably maintained at a pH of about 6.7 to about 7.1, which is a neutral pH. The slurry may be maintained at such a pH range through the use of a buffer system, which acts to stabilize the pH. The buffer system may comprise an organic acid and the salt of an organic acid. Examples of such a buffer system include acetic acid/potassium acetate, citric acid/potassium citrate, carbonic acid/potassium bicarbonate, and phosphoric acid/potassium phosphate.

The slurry may include an oxidizer, preferably periodic acid (HIO₄) in a molar concentration ranging from about 0.005M to about 0.05 M. The periodic acid supplies iodate ions (IO⁻₄) that may oxidize (remove electrons from) metals, including noble metals, such as ruthenium, for example. In the case of ruthenium, the iodate ions of the slurry may oxidize a ruthenium layer according to the following formula:
7Ru(S)+4IO⁻₄+4H⁺→7RuO₂+2I₂+2H₂O

A ruthenium oxide may be formed in a plus 4 oxidation state, such as RuO₂. An advantage of the slurry of the present invention is that because the slurry is maintained at a near neutral pH, the ruthenium layer is oxidized at a plus 4 oxidation state, whereas if the slurry is maintained at a lower pH, as in slurries of the prior art, the ruthenium oxide so formed would likely be in a plus 8 oxidation state (as in RuO₄). RuO₄ is known to those skilled in the art as being highly explosive and toxic, and as such is unsuitable for the manufacture of microelectronic devices.

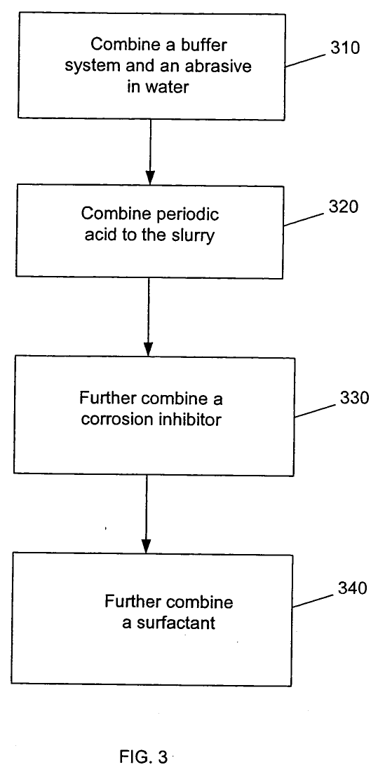

Thus, the slurry of the current embodiment comprises a pH of approximately 4 to about 8 and includes an abrasive, periodic acid as an oxidizer, and a buffer system. The slurry of the present invention may further include benzotriazole as a corrosion inhibitor, as is known in the art. These ingredients are combined, typically with water, to form the slurry. FIG. 3 depicts a flow chart in which, at step 310, a buffer system and an abrasive may be combined in water. At step 320, periodic acid may be further combined to the slurry, and at step 330, a corrosion inhibitor may be further combined to the slurry. At step 340 a surfactant, such as a quaternary salt which may include cetyl trimethyl,ammonium hydroxide (CTAOH) for example, or an ethoxylate ether, such as glucolic acid, exthoxylate, and laurel ether, may be further combined to form the slurry of the present invention.

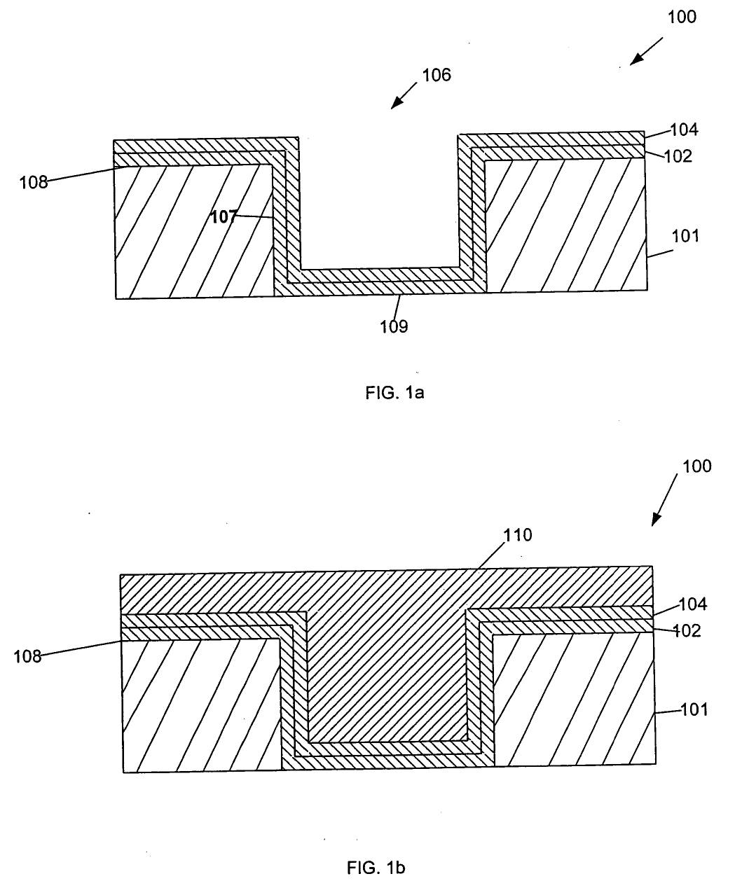

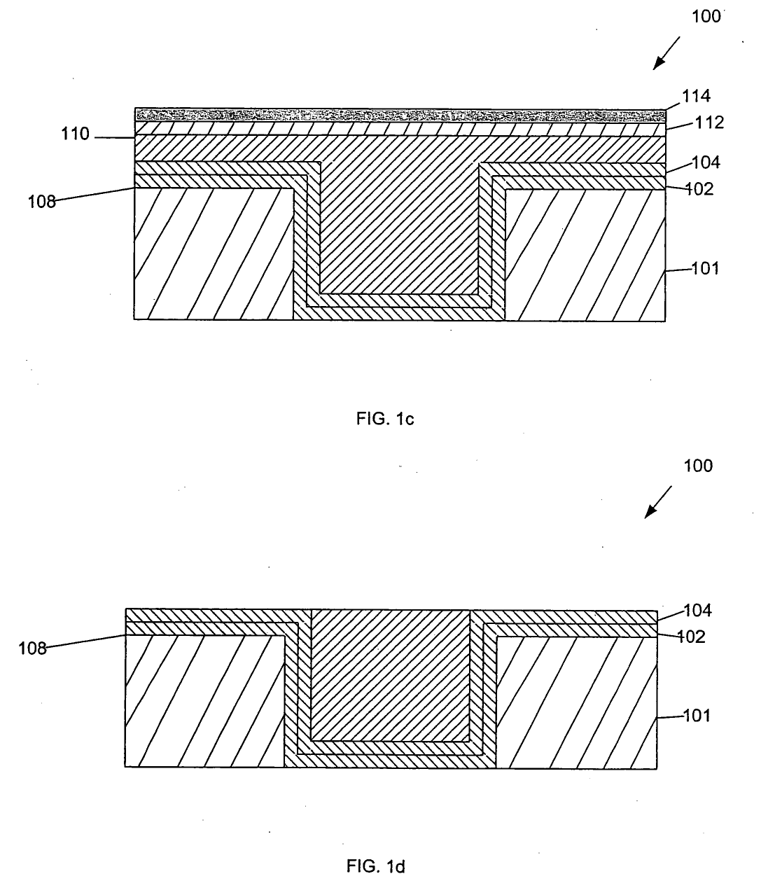

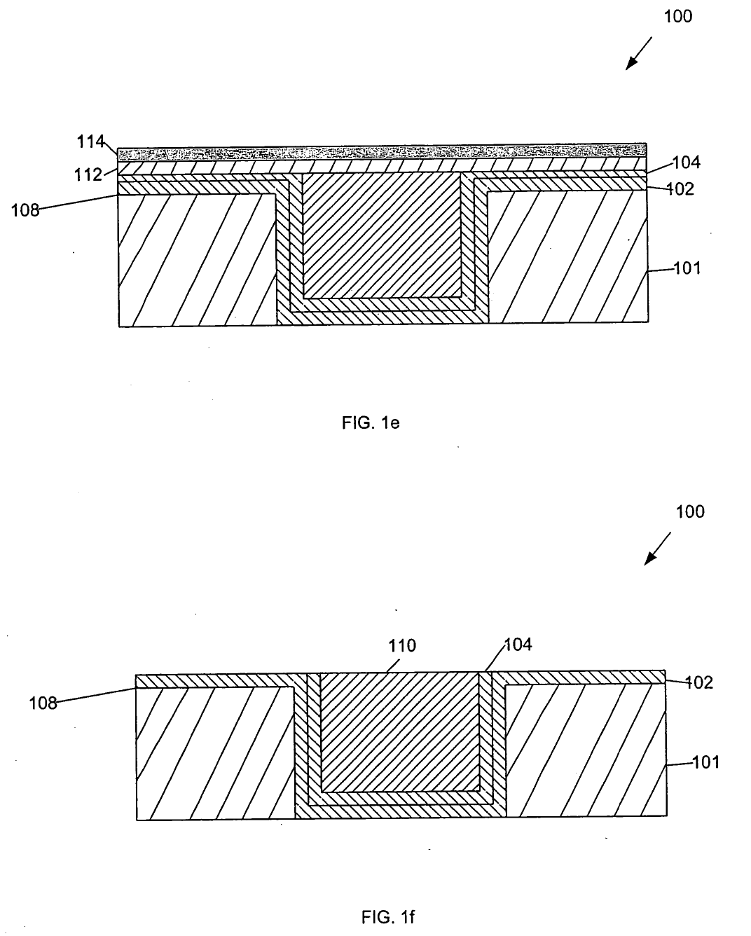

FIGS. 1a-1f illustrate an embodiment of a method of forming a microelectronic structure by chemically mechanically polishing material layers utilizing the slurry of the present invention. FIG. 1a illustrates a portion of a substrate 100 that may comprise a dielectric 101, such as an interlayer dielectric layer (ILD), as is well known in the art. The substrate 100 may further comprise a recess 106. An adhesion layer 102 may be formed on the bottom 109 and the sidewalls 107 of the recess 106, as well as on a first surface 108 of the substrate 100. Various materials may be used as the adhesion layer 102, such as titanium, titanium nitride, tantalum, tantalum nitride and combinations thereof. The adhesion layer may be formed by various deposition techniques known in the art, and as such will not be discussed further herein.

A barrier layer 104 may be disposed on the adhesion layer 102. The barrier layer 104 may comprise a noble metal or a noble metal oxide, and may comprise ruthenium oxide, ruthenium, rhenium, rhodium, palladium, silver, osmium, iridium, platinum, and gold and combinations thereof. The barrier layer 104 may be deposited on the adhesion layer 102 using any number of deposition processes known in the art, such as various sputter deposition techniques known to those skilled in the art. In a preferred embodiment, the barrier layer 104 may comprise a ruthenium oxide layer, which may then act as a shunt by providing a conductive path that allows a microelectronic structure, such as an interconnect structure, to remain functional even if a void forms in the interconnect structure.

The barrier layer 104 may also act as a seed layer for a metal layer 110 that may be formed on the barrier layer 104 (FIG. 1b). The metal layer 110 may be electroplated using various electroplating techniques that are well known in the art, or may be formed using a vapor deposition process. The barrier layer 104 may further act as a barrier to outdiffusion from the metal layer 110. The metal layer 110 may preferably comprise copper, or may be made of another metal, such as tungsten.

As shown in FIG. 1c, a slurry 114, of the aforedescribed kind, is then applied over the metal layer 110. In one embodiment, the slurry 114 may comprise a molar concentration from about 0.01 to about 0.06 of periodic acid, and a citric acid buffer system. The pH of the slurry may be maintained from about 4 to about 8, and is preferably between about 6.8 to about 7.1. As is well known, during a typical chemical mechanical polishing process, a wafer may be placed face down on a rotating table covered with a polishing pad, which has been coated with a slurry, such as the slurry 114 of the present invention. A carrier, which may be attached to a rotatable shaft, is used to apply a downward force against the backside of the wafer. By applying the downward force, and rotating the wafer, while simultaneously rotating a pad having the slurry thereon, a desired amount of material may be removed from the surface of a thin film, such as the metal layer 110 of the present invention.

During the chemical mechanical polishing process an oxidized portion 112 of the metal layer 110 that is formed during the chemical mechanical polishing process may be removed in the manner previously described. It will be appreciated by those skilled in the art that the slurry may further comprise an abrasive, such as silica, zirconia, alumina and/or ceria, in a quantity sufficient to assist in the removal of the oxidized portion 112.

In the current embodiment, a down force of approximately 1.5 psi, a wafer rotational speed of approximately 150 rpm, and a slurry flow rate of approximately 60 ccm may be applied during the chemical mechanical polishing process. It will be understood that the various parameters of the chemical mechanical polishing process may be varied depending upon the particular application. The removal rate of the metal layer 110 that comprises a copper metal may be from about 250 to about 800 angstroms per minute in the current embodiment. The chemical mechanical polishing process may be continued, as shown in FIG. 1d, the metal layer 110 is substantially removed and the underlying barrier layer 104 is exposed (FIG. 1d).

As shown in FIG. 1e, the slurry 114 may be applied to the exposed barrier layer 104. The slurry 114 at this step may comprise a molar concentration of about 0.004 to about 0.006 molar of periodic acid, a citric acid buffer system, a down force of approximately 1.5 psi, a wafer rotational speed of approximately 150 rpm, and a slurry flow rate of approximately 60 ccm. The pH of the slurry may be maintained from about 4 to about 8, and is preferably between about 6.8 to about 7.1. The removal rate of the barrier layer 104 that comprises a ruthenium, or a ruthenium oxide material may be from about 900 to about 1500 angstroms per minute in the current embodiment. I will be appreciated by those skilled in the art that as the pH of the slurry 114 is decreased, the removal rate of the barrier layer 104 comprising a ruthenium material tends to increase. The chemical mechanical polishing process is repeated until, as shown in FIG. 1f, the barrier layer 104 is removed.

In another embodiment, the slurry may comprise a molar concentration of about 0.01 to about 0.06 periodic acid. The pH of the slurry may be maintained from about 4 to about 8, and is preferably between about 6.8 to about 7.1. In this case, the etch rate of the barrier layer that comprises a ruthenium material may be at least about 1,000 angstroms per minute.

Thus, a microelectronic structure (FIG. 1f), such as a conductive interconnect structure as is well known in the art, may be formed using the slurry and methods of the present invention.

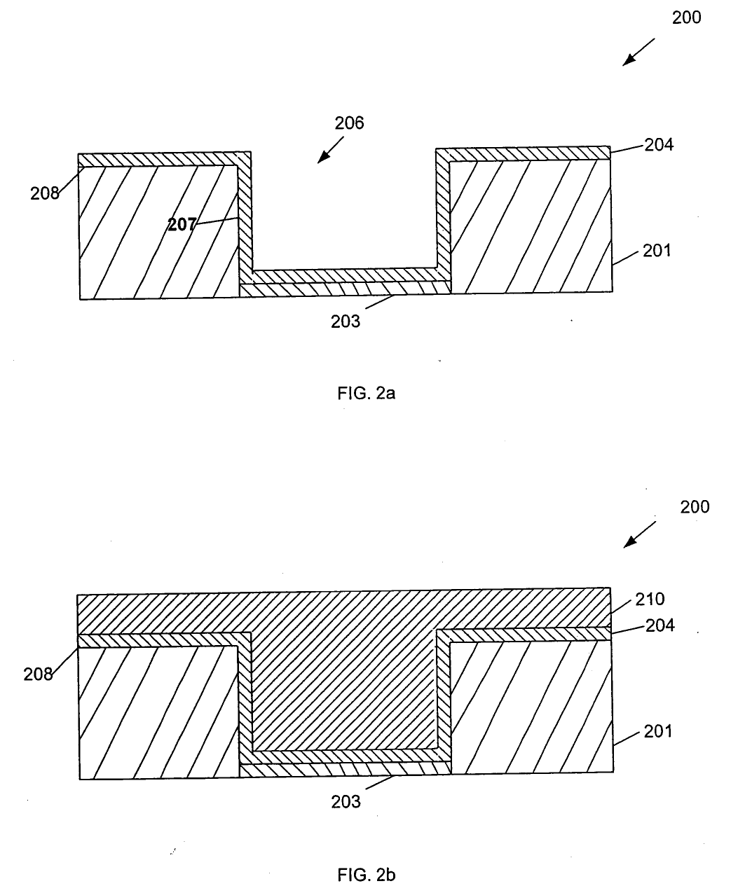

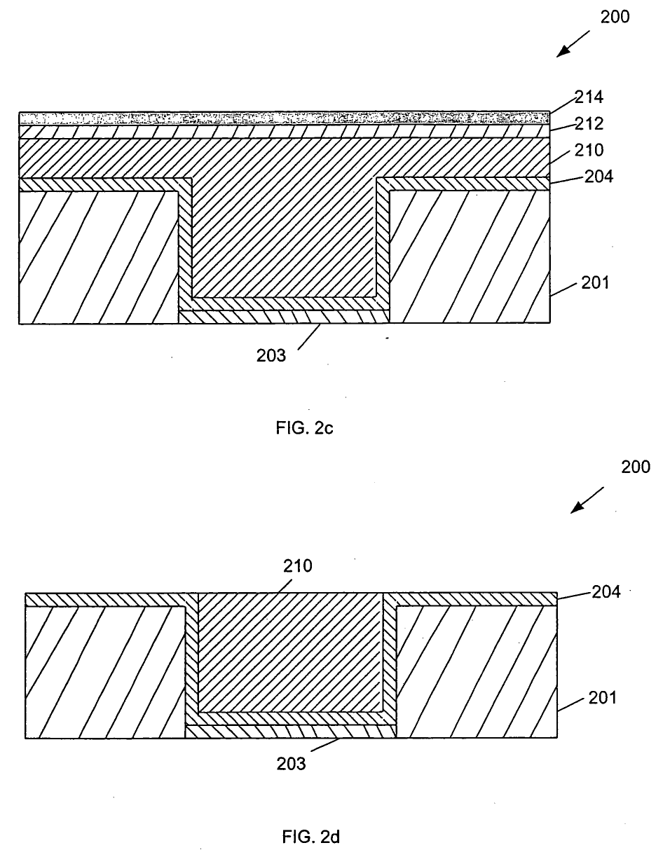

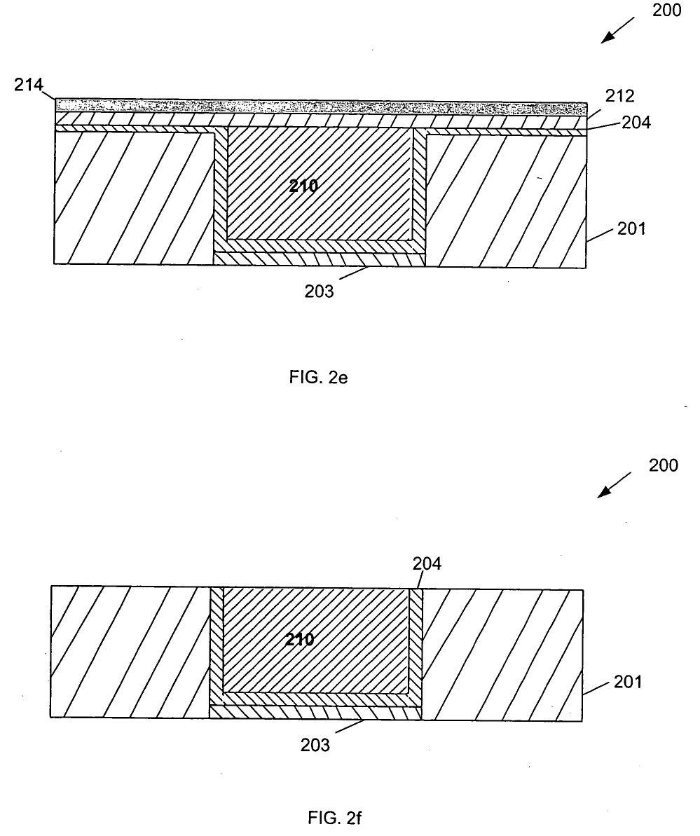

FIGS. 2a-2f illustrate another embodiment of a method of forming a microelectronic structure by chemically mechanically polishing material layers utilizing the slurry of the present invention. FIG. 2a illustrates a portion of a substrate 200 that that may be provided that may comprise a dielectric 201, such as an interlayer dielectric layer (ILD), as is well known in the art. The substrate 200 may further comprise a recess 206.

A dielectric layer 203 may be disposed on the bottom 207 of the recess 206. The dielectric layer 203 may be a gate dielectric layer as is well known in the art. The dielectric layer 203 may also comprise a high k dielectric layer, and may comprise materials selected from the group consisting of as hafnium oxide, hafnium silicon oxide, lanthanum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate.

A work function layer 204 may be disposed on the dielectric layer 203 as well as on the sidewalls 207 of the recess 206 and on a first surface 208 of the substrate 200. The work function layer 204 may comprise ruthenium, ruthenium oxide, titanium nitride, titanium, aluminum, titanium carbide, aluminum nitride, and combinations thereof.

The work function layer 204 may be formed using various deposition techniques as are well known in the art. The work function layer 204 may preferably comprise impurities that are added to the work function layer 204 that may that raise or lower the work function of the work function layer 204. The impurities may be added to the work function layer 204 utilizing various doping techniques well known in the art, such as ion implantation or insitu doping techniques. Those impurities may comprise lanthanide metals, alkali metals, alkaline earth metals, scandium, zirconium, hafnium, aluminum, titanium, tantalum, niobium, tungsten, nitrogen, chlorine, oxygen, fluorine, and bromine. The amount of impurities that may be included in the work function layer 204 may vary depending upon the application, but is preferably a sufficient amount to shift the work function of the work function layer by at least about 0.1 eV.

A fill metal layer 210 may be disposed on the work function layer 204 (FIG. 2b). The fill metal layer 210 may comprise copper, titanium, titanium nitride, tungsten and combinations thereof, but may also comprise other conductive materials. In one embodiment, the fill metal layer may comprise a copper material. A slurry 214 may be applied to the fill metal layer 210 (FIG. 2c), which removes an oxidized portion 212 of the fill metal layer 214. In one embodiment, the slurry may comprise a molar concentration of about 0.01 to about 0.06 periodic acid, and a citric acid buffer system. The pH of the slurry may be maintained from about 4 to about 8, and is preferably between about 6.8 to about 7.1. The removal rate of the fill metal layer 210 that comprises a copper metal may be from about 250 to about 800 angstroms per minute in the current embodiment.

Upon removal of the fill metal layer 210, the underlying work function layer 204 is exposed (FIG. 2d). A slurry 214 may be applied to the work function layer 210 (FIG. 2e), which removes an oxidized portion 212 of the work function layer 214. In one embodiment, the slurry may comprise a molar concentration of about 0.004 to about 0.006 of periodic acid, and a citric acid buffer system. The pH of the slurry may be maintained from about 4 to about 8, and is preferably between about 6.8 to about 7.1. The removal rate of the work function layer 210 that comprises a ruthenium or a ruthenium oxide material may be from about 900 to about 1500 angstroms per minute in the current embodiment.

In another embodiment utilizing the above mentioned slurry, a work function layer comprising a titanium nitride, aluminum nitride material may be removed at a removal rate of about 500 angstroms per minute to about 700 angstroms per minute.

In another embodiment utilizing the above mentioned slurry, a work function layer comprising a titanium aluminum material may be removed at a removal rate of about 150 angstroms per minute to about 350 angstroms per minute.

In another embodiment, the slurry may comprise a molar concentration of about 0.01 to about 0.06 of periodic acid, and a citric acid buffer system. The pH of the slurry may be maintained from about 4 to about 8, and is preferably between about 6.8 to about 7.1. The removal rate of the work function layer 210 that comprises a ruthenium, or ruthenium oxide material may removed at a removal rate of at least about 1000 angstroms per minute in the current embodiment.

Thus a metal gate structure may be formed (FIG. 2f that comprises the fill metal layer 210 disposed on the work function layer 104 that is disposed on the dielectric layer 203. As described above, the present invention provides a slurries and methods and associated structures of forming microelectronic devices utilizing the slurries of the present invention. The slurries, methods and structures of the present invention enable the removal of noble metals, such as ruthenium, from microelectronic devices.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that the fabrication of a multiple layer structure atop a substrate, such as a silicon substrate, to manufacture a microelectronic device is well known in the art. Therefore, it is appreciated that the Figures provided herein illustrate only portions of an exemplary microelectronic device that pertains to the practice of the present invention. Thus the present invention is not limited to the structures described herein.

What is claimed is:

1-10. (canceled)

11. A method of forming a microelectronic structure comprising:
providing a substrate comprising a barrier layer disposed on an adhesion layer, wherein the adhesion layer is disposed within a recess and on a first surface of a substrate; and
removing the barrier layer from the adhesion layer with a slurry comprising periodic acid and a pH from about 4 to about 8.

12. The method of claim 11 wherein providing a substrate comprising a barrier layer comprises providing a substrate comprising a material selected form the group comprising ruthenium oxide, ruthenium, rhenium, rhodium, palladium, silver, osmium, iridium, platinum, and gold and combinations thereof.

13. The method of claim 11 wherein removing the barrier layer from the adhesion layer with a slurry comprising periodic acid and a pH from about 4 to about 8 comprises removing the barrier layer from the adhesion layer with a slurry comprising periodic acid at a molar concentration from about 0.01 M to about 0.06M, and a pH from about 4 to about 8.

14. The method of claim 13 wherein removing the barrier layer from the adhesion layer with a slurry comprises removing a ruthenium oxide layer from the adhesion layer with a slurry at a removal rate of about 900 angstroms per minute to about 1500 angstroms per minute.

15. The method of claim 11 wherein providing a substrate comprising a barrier layer disposed on an adhesion layer, wherein the adhesion layer is disposed within a recess and on a first surface of a substrate comprises providing a substrate comprising a metal layer disposed on a barrier layer that is disposed on an adhesion layer, wherein the adhesion layer is disposed within a recess and on a first surface of a substrate.

16. The method of claim 15 wherein removing the metal layer from the barrier layer comprises removing a copper layer from the barrier layer.

17. The method of claim 16 further comprising removing the copper layer from the barrier layer with a slurry at a removal rate of about 250 angstroms per minute to about 800 angstroms per minute.

18. The method of claim 11 wherein removing the barrier layer from the adhesion layer with a slurry comprising periodic acid and a pH from about 4 to about 8 comprises removing the metal layer from the adhesion layer with a slurry comprising periodic acid at a molar concentration from about 0.004M to about 0.006M, and a pH from about 4 to about 8.

19. The method of claim 18 wherein removing the barrier layer from the adhesion layer with a slurry comprises removing a ruthenium layer from the adhesion layer with a slurry at a removal rate of at least about 1000 angstroms per minute.

20. The method of claim 11 wherein providing a substrate comprising a barrier layer disposed on an adhesion layer, comprises providing a substrate comprising a barrier layer disposed on a material selected from the group consisting of titanium, titanium nitride, tantalum, tantalum nitride and combinations thereof.

21. A method of forming a microelectronic structure comprising:
providing a substrate comprising a recess wherein a work function layer is disposed within the recess and on a first surface of the recess, and wherein a fill metal layer is disposed on the work function layer; and
forming a metal gate electrode by:
removing the fill metal layer until the underlying work function layer is exposed by utilizing a slurry comprising periodic acid at a pH from about 4 to about 8; and
removing the work function layer from the first surface of the recess with the slurry.

22. The method of claim 21 wherein removing the fill metal layer comprises removing the fill metal layer by utilizing chemical mechanical polishing.

23. The method of claim 21 wherein removing the work function layer comprises removing the work function layer utilizing chemical mechanical polishing.

24. The method of claim 21 wherein providing a substrate comprising a recess wherein a work function layer is disposed within the recess comprises providing a substrate comprising a recess wherein a work function layer selected from the group comprising ruthenium, ruthenium oxide, titanium nitride, titanium, aluminum, titanium carbide, aluminum nitride, and combinations thereof is disposed within the recess.

25. The method of claim 21 wherein providing a substrate comprising a recess wherein a work function layer is disposed within the recess and on a first surface of the recess comprises providing a substrate comprising a recess wherein a work function layer includes a sufficient amount of an impurity to shift the work function of the work function layer by at least about 0.1 eV.

26. The method of claim 25 wherein providing a substrate comprising a recess wherein a work function layer includes a sufficient amount of an impurity comprises providing a substrate comprising a recess wherein a work function layer includes a sufficient amount of an impurity selected from the group consisting of a lanthanide metal, an alkali metal, an alkaline earth metal, scandium, zirconium, hafnium, aluminum, titanium, tantalum, niobium, tungsten, nitrogen, chlorine, oxygen, fluorine, and bromine.

27. The method of claim 21 wherein the metal fill layer is selected from the group consisting of copper, titanium, titanium nitride, tungsten and combinations thereof.

28. The method of claim 21 wherein removing the work function comprises removing the work function layer by utilizing a slurry comprising periodic acid at a pH from about 4 to about 8 at a molar concentration from about 0.01M to about 0.06M.

29. The method of claim 28 wherein removing the work function layer comprises removing a ruthenium layer at a removal rate of about 900 angstroms per minute to about 1500 angstroms per minute.

30. The method of claim 28 wherein removing the work function layer comprises removing a titanium nitride, aluminum nitride layer at a removal rate of about 500 angstroms per minute to about 700 angstroms per minute.

31. The method of claim 28 wherein removing the work function layer comprises removing a titanium aluminum layer at a removal rate of about 150 angstroms per minute to about 350 angstroms per minute.

32-35. (canceled)
